(19) United States
(12) Patent Application Publication
(10) Pub. No.: US 2013/0114219 A1
(43) Pub. Date: May 9, 2013

(54) OPTO-ELECTRONIC FRONTPLANE SUBSTRATE

(71) Applicants: Sean Matthew Garner, Elmira, NY (US); Mingqian He, Horseheads, NY (US); Wendell Porter Weeks, Corning, NY (US)

(72) Inventors: Sean Matthew Garner, Elmira, NY (US); Mingqian He, Horseheads, NY (US); Wendell Porter Weeks, Corning, NY (US)

(21) Appl. No.: 13/660,494

(22) Filed: Oct. 25, 2012

Related U.S. Application Data
(60) Provisional application No. 61/556,934, filed on Nov. 8, 2011.

(51) Int. Cl. H05K 1/03; B32B 17/06; B32B 38/00; H05K 1/16; B32B 37/16

(52) U.S. Cl. 361/750; 156/60; 156/280; 428/428

(57) ABSTRACT

Frontplane articles are described utilizing laminated glass substrates, for example, ion-exchanged glass substrates, with flexible glass and with opto-electronic devices which may be sensitive to alkali migration are described along with methods for making the articles.

This application claims the benefit of priority under 35 U.S.C. §119 of U.S. Provisional Application Ser. No. 61/556,934 filed Nov. 8, 2011 the content of which is relied upon and incorporated herein by reference in its entirety.

### FIELD

This disclosure is directed to opto-electronic devices using laminated structures and in particular to opto-electronic devices using strengthened glass as frontplane substrates with flexible glass layers or polymer layers and methods of making the same.

### BACKGROUND

Currently there is an interest in making displays and similar devices thin, light weight, and mechanically durable. The current approach is to use a strengthened glass cover to protect a separately fabricated display. This current approach uses multiple substrates and results in a relatively thick packaged device. There is an interest in integrating the strengthened cover with the display to achieve thinner, lighter, and more durable devices than currently exists. Also there is an interest in achieving mechanically reliable conformal or non-flat displays.

The different approaches taken to-date in making thinner devices have included fabricating a display or other device panel and chemically etching the thickness. The strengthened cover is then attached to the frame in proximity or directly bonded to the display. If the direct bonding occurs, it is performed as a step in device packaging and not part of the panel fabrication.

It would be advantageous to create a mechanically durable electronic device frontplane using strengthened glass substrates.

### SUMMARY

Mechanically strengthened ion-exchanged glass as a substrate and a layer of flexible thin glass for a barrier to fabricate active electronic devices has been described in commonly owned U.S. Provisional Patent Application No. 61/483,205 filed on May 6, 2011. Since alkali-free flexible glass can be also used as frontplane which generally acts as color filter for Liquid Crystal Display (LCD), we believe that laminating the flexible glass to a mechanically durable glass such as ion-exchanged glass as front glass can generate both a mechanical strong front cover and an alkaline free thinner, lighter glass surface.

In contrast, the disclosure differs from the previous approaches in that the strengthened cover is integrated directly into the device structure as part of the panel fabrication process. By integrating the strengthened glass as part of panel fabrication, a thinner, lighter, and more durable device may be achieved. Also, this approach creates a more efficient process for fabricating conformal displays.

The disclosure relates to a device design that integrates the strengthened cover to the display frontplane. Specifically embodiments include concepts for a flexible glass frontplane bonded to a strengthened cover and a frontplane fabricated directly onto the strengthened cover. This device configuration and method of making the device have not been reported previously.

Embodiments may provide one or more of the following advantages: mechanical reliability—by integrating the frontplane directly to the cover glass, a higher level of mechanical reliability is achieved. Direct bonding of flat frontplanes has previously occurred in displays and touch panels. In one embodiment, the frontplane is directly bonded to the cover glass as part of the panel assembly or fabrication process; processing capability—by integrating a flexible glass frontplane substrate to the cover glass, additional processing options are achieved. The flexible glass can be optimized for roll-to-roll or other processing and then be laminated to the cover glass after fabrication is complete. This approach utilizes roll-to-roll processing when it is beneficial. It allows bonding of a fully or partially fabricated flexible glass frontplane to a non-flat cover glass. It also utilizes sheet processing of flexible glass bonded to cover glass when is an advantage to do so; thinner and lighter weight—by integrating the cover glass and frontplane, a thinner and lighter weight device is achieved; and/or this approach may eliminate unnecessary device thickness and/or weight.

One possibility is to use strengthened glass, such as Gorilla® (registered Trademark of Corning Incorporated) Glass as the frontplane substrate.

One embodiment is a frontplane substrate for an opto-electronic device comprising a glass substrate having a first surface and a second surface, and a flexible glass layer having a capability of bending to a radius of 30 cm or greater and having a first surface and a second surface, wherein the first surface of the flexible glass layer is adjacent to the second surface of the glass substrate.

Another embodiment is a method comprising providing a glass substrate having a first surface and a second surface and applying a flexible glass layer having a capability of bending to a radius of 30 cm or greater and having a first surface and a second surface, wherein the first surface of the flexible glass layer is adjacent to the second surface of the glass substrate.

Additional features and advantages of the will be set forth in the detailed description which follows, and in part will be readily apparent to those skilled in the art from the description or recognized by practicing the invention as described in the written description and claims hereof, as well as the appended drawings.

It is to be understood that both the foregoing general description and the following detailed description are merely exemplary of the invention, and are intended to provide an overview or framework for understanding the nature and character of the invention as it is claimed.

The accompanying drawings are included to provide a further understanding of the invention, and are incorporated in and constitute a part of this specification. The drawings illustrate one or more embodiment(s) of the invention and together with the description serve to explain the principles and operation of the invention.

### BRIEF DESCRIPTION OF THE DRAWINGS

The invention can be understood from the following detailed description either alone or together with the accompanying drawing figures.

FIG. 1 is an illustration of a frontplane substrate according to one embodiment.

FIG. 2 is an illustration of a frontplane substrate according to one embodiment.

FIG. 3 is a graph showing ring on ring load failures of exemplary ion-exchanged glass substrates at various thicknesses.

### DETAILED DESCRIPTION

Reference will now be made in detail to various embodiments.

As used herein, the term “substrate” can be used to describe either a substrate or a superstrate depending on the configuration of the device. For example, the substrate is a superstrate, if when assembled into, for example, a photovoltaic cell, it is on the light incident side of a photovoltaic cell. The superstrate can provide protection for the photovoltaic materials from impact and environmental degradation while allowing transmission of the appropriate wavelengths of the solar spectrum. Further, multiple photovoltaic cells can be arranged into a photovoltaic module. Photovoltaic device can describe either a cell, a module, or both.

As used herein, the term “adjacent” can be defined as being in close proximity. Adjacent structures may or may not be in physical contact with each other. Adjacent structures can have other layers and/or structures disposed between them. The adjacent layers may be separated by one or layers including one or more air gaps.

Embodiments comprise a device frontplane bonded or fabricated on a strengthened cover glass. The frontplane can be fabricated onto a flexible glass substrate and then bonded to the cover glass or the frontplane can be fabricated directly onto the cover glass itself.

The frontplane can comprise structures such as a frontplane for e-paper. This may include an electrophoretic or electrochromic frontplane. The frontplane may also comprise a color filter frontplane for liquid crystal or e-paper displays as well as a touch sensor substrate. The frontplane may also comprise a photovoltaic device frontplane. In general, the device frontplane is the substrate that semiconductor elements are not formed on and is usually opposite from the backplane. The strengthened cover glass can comprise an ion-exchanged or other strengthened substrate. Examples of this include Gorilla® Glass and FIT substrates.

The flexible glass substrate can comprise a glass substrate <300 um thick with or without protective coatings. Examples of flexible glass substrates compatible with frontplane fabrication include fusion drawn Eagle XG®, (registered Trademark of Corning Incorporated), re-drawn Eagle XG®, and slot drawn 0211. For frontplane fabrication, the flexible glass can be used as discrete sheets or as a roll of spooled glass. The spooled flexible glass offers the ability to fabricate the frontplane in an efficient roll-to-roll process. After the roll-to-roll frontplane fabrication, the discrete device frontplanes can be singulated and bonded to individual cover glass substrates. This allows the use of roll-to-roll processing when it is beneficial and the use of flexible glass bonded to the cover glass when sheet based processing is required. For example, the cover glass can act as a processing carrier to the flexible glass if specific sheet based processing is desired after a certain point. Fabrication of devices on the flexible glass also allows bonding to non-planar strengthened cover glass substrates. Device fabrication directly on the curved or non-planar cover glass would not be practical from a processing point of view. Frontplane fabrication first on flexible glass and then bonding to a curved cover glass as shown in FIG. 2, though, is possible.

As another note, the present disclosure enables one approach for the assembly of conformal displays. If devices are assembled in the flat state, a certain amount of strain will occur when the device is then bent to a given radius. This induced strain may affect the device performance. For example, if a LCD is assembled flat and then bent, the resulting strain in the liquid crystal of other layers may resort in a distorted or lower quality image. With the present disclosure, though, the frontplane can first be fabricated and then bonded to the curved cover glass. Next the backplane can be assembled to the frontplane. By building the device in this order, the adhesives and other material bonding the frontplane and backplane are in a stress-free state when curved.

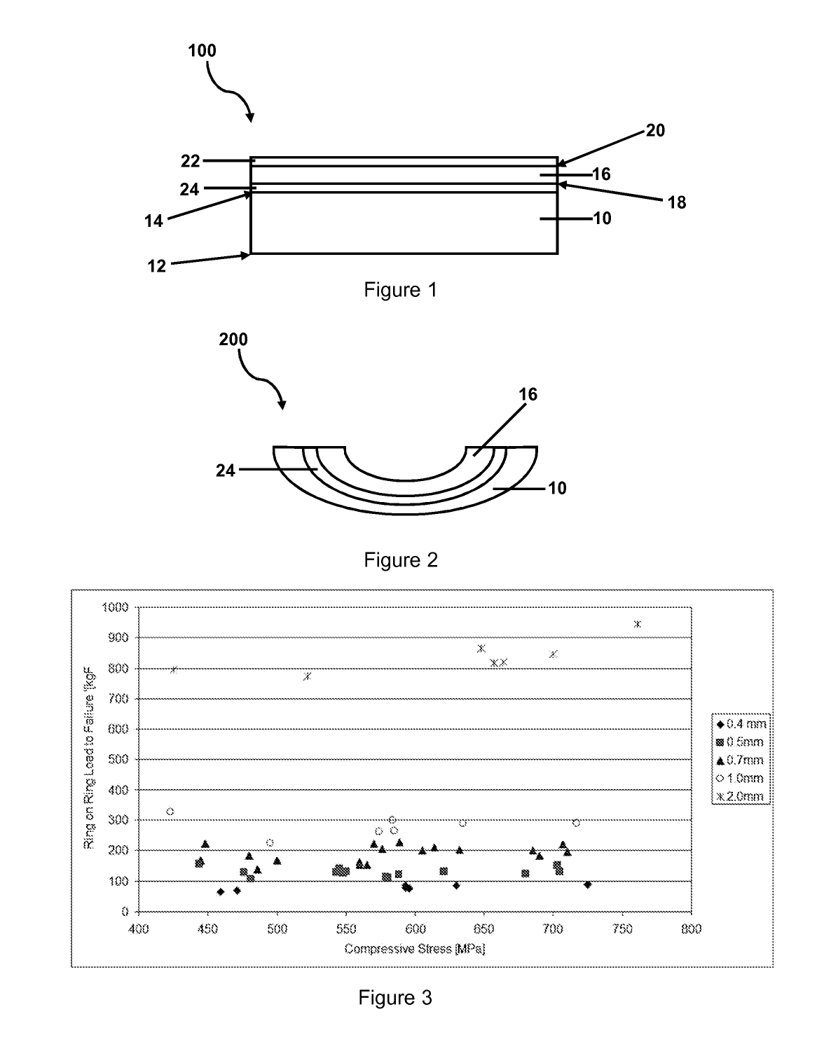

One embodiment, as shown in FIG. 1, is a frontplane substrate 100 for an opto-electronic device comprising a glass substrate 10 having a first surface 12 and a second surface 14, and a flexible glass layer 16 having a capability of bending to a radius of 3 cm or greater and having a first surface 18 and a second surface 20, wherein the first surface 18 of the flexible glass layer 16 is adjacent to the second surface 14 of the glass substrate 10. In one embodiment as shown in FIG. 1, an opto-electronic device 22 is adjacent to the second surface 20 of the flexible glass layer 16.

In one embodiment, the flexible glass layer is disposed on the glass substrate, for example, the flexible glass layer is in physical contact with the glass substrate. The flexible glass layer, in one embodiment, is an alkali-free glass. Alkali-free glass can be free of intentionally added alkali, or for example, have an alkali content of 0.05 weight percent or less, for example, 0 weight percent alkali. The flexible glass layer can be in the form of a glass sheet.

In one embodiment, the flexible glass layer or sheet is optically transparent. The flexible glass layer can be optically clear or optically clear and optically transparent. Optically clear can mean free from visible color to the naked eye.

The flexible glass layer can be made from an alkali-free glass composition and drawn to thicknesses of <300 um. For example, the flexible glass can have an average thickness of 300 um or less, for example, 200 um or less, for example, 100 um or less, for example, 50 um or less. In one embodiment, the flexible glass layer has an average thickness of 150 um or less. The flexible glass could have the dimensional tolerances and surface quality of typical fusion drawn liquid crystal display (LCD) substrates to enable the fabrication of an opto-electronic device on its surface. In some embodiments, the flexible glass is capable of a minimum bend radius of 30 cm or greater, for example, 25 cm or greater, for example, 20 cm or greater, for example, 15 cm or greater, for example, 10 cm or greater, for example, 5 cm or greater, for example, 3 cm or greater, or 1 cm or greater. In some embodiments, the flexible glass is capable of a minimum bend radius of from 30 cm to 1 cm, for example, 25 cm to 1 cm, for example, 20 cm to 1 cm, for example, 15 cm to 1 cm, for example, 10 cm to 1 cm, for example, 5 cm to 1 cm, for example, 3 cm to 1 cm. The bend radius ranges described herein are directed towards an increasingly tighter bend in the glass, wherein 10 cm is a smaller and tighter bend than 30 cm. A 0 cm bend radius would describe a glass which is has no bend. The flexible glass is capable of this minimum bend radius without cracking, shattering, and/or breaking.

In one embodiment, the device is disposed on the flexible glass layer, for example, the device is in physical contact with the flexible glass layer.

In another embodiment, the device is spaced apart from the flexible glass layer. There can be multiple layers in the space between the device and the flexible glass layer, for example, a polymer layer(s), an adhesive layer(s), the space can comprise air, and/or a color filter layer or regions.

The frontplane substrate, according to one embodiment and shown in FIG. 1, further comprises an optional bonding layer 24 disposed between the flexible glass layer 16 and the glass substrate 10. In one embodiment, the bonding layer is a laminate layer and the flexible glass layer is laminated to the glass substrate. This laminate layer could be an organic or non-organic adhesive film. As another example, the bonding layer 24 could be a photo or thermally curing adhesive layer. Pressure sensitive adhesives, photo curable organic adhesives, silicone films and thermally curing adhesives, inorganic layers such as frits are examples of bonding layer 24.

In one embodiment, the glass substrate is in the form of a glass sheet. The glass substrate, in one embodiment, comprises a strengthened glass having a Vickers crack initiation threshold of at least 20 kgf. The glass substrate can be an ion-exchanged glass. The glass substrate can be planar or non-planar, for example, the glass substrate can be curved with a single or variable radius.

According to some embodiments, the glass substrate has a thickness of 4.0 mm or less, for example, 3.5 mm or less, for example, 3.2 mm or less, for example, 3.0 mm or less, for example, 2.5 mm or less, for example, 2.0 mm or less, for example, 1.9 mm or less, for example, 1.8 mm or less, for example, 1.5 mm or less, for example, 1.1 mm or less, for example, 0.5 mm to 2.0 mm, for example, 0.5 mm to 1.1 mm, for example, 0.7 mm to 1.1 mm. Although these are exemplary thicknesses, the glass substrate can have a thickness of any numerical value including decimal places in the range of from 0.1 mm up to and including 4.0 mm.

In one embodiment, a functional layer is disposed on the first surface of the glass substrate. The functional layer can be selected from an anti-glare layer, an anti-smudge layer, a self-cleaning layer, an anti-reflection layer, an anti-fingerprint layer, an optically scattering layer, and combinations thereof.

In one embodiment, the strengthened glass substrate is in the form of a glass sheet. The strengthened glass substrate can be an ion-exchanged glass. The strengthened glass substrate can be planar or non-planar, for example, the strengthened glass substrate can be curved with a single or variable radius. As shown in FIG. 2, the flexible glass substrate 16 can be bonded to the concave surface of the curved strengthened glass substrate 10. An alternative example not shown is that the flexible glass substrate 16 can also be bonded to the convex surface of the curved strengthened glass substrate 10.

Glasses designed for use in applications such as in consumer electronics and other areas where high levels of damage resistance are desirable are frequently strengthened by thermal means (e.g., thermal tempering) or chemical means. Ion-exchange is widely used to chemically strengthen glass articles for such applications. In this process, a glass article containing a first metal ion (e.g., alkali cations in Li₂O, Na₂O, etc.) is at least partially immersed in or otherwise contacted with an ion-exchange bath or medium containing a second metal ion that is either larger or smaller than the first metal ion that is present in the glass. The first metal ions diffuse from the glass surface into the ion-exchange bath/medium while the second metal ions from the ion-exchange bath/medium replace the first metal ions in the glass to a depth of layer below the surface of the glass. The substitution of larger ions for smaller ions in the glass creates a compressive stress at the glass surface, whereas substitution of smaller ions for larger ions in the glass typically creates a tensile stress at the surface of the glass. In some embodiments, the first metal ion and second metal ion are monovalent alkali metal ions. However, other monovalent metal ions such as Ag⁺, Tl⁺, Cu⁺, and the like may also be used in the ion-exchange process.

In one embodiment, the glass substrate is a soda lime glass, an aluminoborosilicate, an alkalialuminoborosilicate, an aluminosilicate, or an alkalialuminosilicate. In one embodiment, the glass substrate is a strengthened glass substrate. In one embodiment, the strengthened glass substrate is an ion-exchanged glass substrate.

In one embodiment, the glass substrate comprises a strengthened glass wherein the glass is ion-exchanged to a depth of layer of at least 20 μm from a surface of the glass.

In one embodiment, the strengthened glass substrates described herein, when chemically strengthened by ion-exchange, exhibit a Vickers initiation cracking threshold of at least about 5 kgf (kilogram force), in some embodiments, at least about 10 kgf, in some embodiments and, in other embodiments, at least about 20 kgf, for example, at least about 30 kgf. FIG. 3 is a graph showing ring on ring load failures of exemplary ion-exchanged glass substrates, for example, Gorilla® glass at various thicknesses.

In one embodiment, a functional layer is disposed on the first surface of the strengthened glass substrate. The functional layer can be selected from an anti-glare layer, an anti-smudge layer, a self-cleaning layer, an anti-reflection layer, an anti-fingerprint layer, an anti-splintering layer, an optically scattering layer, and combinations thereof.

Another embodiment is a method comprising providing a glass substrate having a first surface and a second surface, and applying a flexible glass layer having a capability of bending to a radius of 3 cm or greater and having a first surface and a second surface, wherein the first surface of the flexible glass layer is adjacent to the second surface of the glass substrate.

In one embodiment, the method further comprises forming an opto-electronic device adjacent to the second surface of the flexible glass layer.

In one embodiment, the method comprises applying a very thin layer of flexible glass sheet on an ion-exchange glass sheet. An alkali-free flexible glass sheet can be bonded with either an organic adhesive or a glass-glass bonding process, for example, a roll-to-roll method. The substantially alkali-free flexible glass sheet can effectively block the migration of alkali ions from the ion-exchanged glass sheet. The opto-electronic device can be fabricated on the flexible glass sheet after the flexible glass sheet is bonded to the ion-exchanged glass sheet, according to one embodiment.

A polymer layer can be used to bond the flexible glass to the ion-exchanged glass and can be deposited by a solution processing method. The polymer could be either thermally cured (crosslinked) or photo cured (crosslinked).

After the flexible glass layer or the polymer layer is applied to the glass substrate, opto-electronic devices or other intermediate layers, such as a color filter(s), an adhesive layer(s) and/or a polymer layer(s), can be fabricated on the second surface of the flexible glass layer or the polymer layer. For example, an organic TFT device can include: an ion-exchanged glass substrate including the flexible glass layer or the polymer layer. These layers can be stacked in different sequences and can be separated by an air gap. In another approach, the opto-electronic device can be fabricated on an alkali-free flexible glass layer before laminating the flexible glass layer to the ion-exchanged glass substrate. This allows process compatible flexible glass to be used during frontplane fabrication. Bonding it then to the ion-exchanged glass produces a mechanically durable stack.

As mentioned previously, a flexible glass substrate can be bonded to a mechanically durable ion-exchanged glass substrate to produce a composite structure. This composite structure offers the alkali-free flexible glass surface for high quality opto-electronic device fabrication and performance. It also provides the high mechanical durability of the ion-exchanged glass.

The flexible glass layer can be made from an alkali-free glass composition and drawn to thicknesses of <300 um. For example, the flexible glass can have a thickness of 300 um or less, for example, 200 um or less, for example, 100 um or less, for example, 50 um or less. The flexible glass could have the dimensional tolerances and surface quality of typical fusion drawn LCD substrates to enable the fabrication of high performance opto-electronic devices on or near its surface.

The ion-exchanged glass substrate can have a thickness <1.5 mm and have mechanical durability characteristics similar to those typical of Gorilla® Glass and fully integrated touch (FIT) product substrates. For example, it could have a compression layer that enables frontplane fabrication onto device substrates pre-cut to the final size, or it could enable frontplane fabrication on substrates approximately 1 m×1 m in size or greater or similar substrates that are subsequently cut to the finished shape.

The flexible glass can be bonded to the surface of the ion-exchanged glass through lamination or other bonding methods. The flexible glass can have a size equal to the ion-exchanged glass, or the flexible glass can be much smaller and enable several discrete flexible glass pieces to be bonded across the ion-exchanged glass surface. To be compatible with the low temperature processing, the flexible glass can be bonded using a pressure sensitive adhesive (PSA) for example made from silicone or acrylate adhesives. Typical PSA films range from 12.5 to 50 um thick. The flexible glass can also be bonded by use of a curable adhesive applied to either the flexible glass or ion-exchanged glass. This adhesive also can be thermally or UV (photo) cured.

As mentioned previously, opto-electronic devices can be fabricated onto the flexible glass surface either before or after it is bonded to the ion-exchanged glass substrate. If the opto-electronic devices are fabricated before bonding, the devices can be made by methods known in the art such as batch, continuous sheet-fed, or roll-to-roll methods. These methods take advantage of the dimensional stability of flexible glass compared to polymer films.

After the devices have been fully or partially fabricated, high strength cutting methods such as laser cutting can be used, if needed, to singulate individual device substrates. This enables a device frontplane that is mechanically durable with both high strength surfaces and edges.

Embodiments described herein may provide one or more of the following advantages: provide a practical way to fabricate opto-electronic devices on strengthened glass, for example, ion-exchanged glass substrates and promote the use of strengthened glass, for example, ion-exchanged glass as suitable substrates for display backplanes; allow the fabrication of electronic devices on strengthened glass, for example, ion-exchanged glasses without changing the superior compression strength of the glass; and/or provides an easy way to minimize the migration of ions on the ion-exchanged glasses into the electronic devices.

It will be apparent to those skilled in the art that various modifications and variations can be made to the present invention without departing from the spirit or scope of the invention. Thus, it is intended that the present invention cover the modifications and variations of this invention provided they come within the scope of the appended claims and their equivalents.

What is claimed is:

1. A frontplane substrate for an opto-electronic device comprising:
a glass substrate having a first surface and a second surface; and
a flexible glass layer having a capability of bending to a radius of 30 cm or greater and having a first surface and a second surface, wherein the first surface of the flexible glass layer is adjacent to the second surface of the glass substrate.

2. The frontplane substrate according to claim 1, further comprising an opto-electronic device adjacent to the flexible glass layer.

3. The frontplane substrate according to claim 2, wherein the device is disposed on the flexible glass layer.

4. The frontplane substrate according to claim 2, wherein the device is spaced from the flexible glass layer by one or more layers.

5. The frontplane substrate according to claim 4, wherein the one or more layers comprises air, a polymer layer, or an adhesive layer.

6. The frontplane substrate according to claim 2, wherein the device is selected from the group consisting of a photovoltaic device, a thin-film transistor, a diode, a touch-screen device, an electrophoretic device, an electrochromic device, and a display device.

7. The frontplane substrate according to claim 1, wherein the glass is a soda lime glass, an aluminoborosilicate, an alkalialuminoborosilicate, an aluminosilicate, or an alkalialuminosilicate.

8. The frontplane substrate according to claim 1, wherein the flexible glass layer is disposed on the glass substrate.

9. The frontplane substrate according to claim 1, further comprising a bonding layer disposed between the flexible glass layer and the glass substrate.

10. The frontplane substrate according to claim 9, wherein the bonding layer is a laminate layer and the flexible glass layer is laminated to the glass substrate.

11. The frontplane substrate according to claim 1, wherein the flexible glass layer is an alkali-free glass.

12. The frontplane substrate according to claim 1, wherein the flexible glass layer is a glass sheet.

13. The frontplane substrate according to claim 1, wherein the glass substrate is a glass sheet.

14. The frontplane substrate according to claim 1, the glass substrate comprises a strengthened glass wherein the glass is ion-exchanged to a depth of layer of at least 20 μm from a surface of the glass.

15. The frontplane substrate according to claim 1, wherein the glass substrate is an ion-exchanged glass.

16. The frontplane substrate according to claim 1, wherein the glass substrate has a Vickers crack initiation threshold of at least 20 kgf.

17. The frontplane substrate according to claim 1, further comprising a functional layer disposed on the first surface of the glass substrate.

18. The frontplane substrate according to claim 17, wherein the functional layer is selected from an anti-glare layer, an anti-smudge layer, a self-cleaning layer, an anti-reflection layer, an anti-fingerprint layer, an optically scattering layer, and combinations thereof.

19. The frontplane substrate according to claim 1, wherein the glass substrate is curved.

20. A method comprising:
providing a glass substrate having a first surface and a second surface; and
applying a flexible glass layer having a capability of bending to a radius of 30 cm or greater and having a first surface and a second surface, wherein the first surface of the flexible glass layer is adjacent to the second surface of the glass substrate.

21. The method according to claim 20, further comprising forming an opto-electronic device adjacent to the second surface of the flexible glass layer.

22. The method according to claim 20, wherein the flexible glass layer comprises an alkali-free glass and wherein the applying the flexible glass layer comprises disposing the alkali-free glass on the glass substrate prior to forming the device.

23. The method according to claim 20, wherein the flexible glass layer comprises an alkali-free glass and wherein the applying the flexible glass layer comprises disposing the alkali-free glass on the glass substrate after forming the device.

24. The method according to claim 20, wherein the applying the flexible glass layer to the glass substrate comprises rolling the layer and the substrate together such that a vacuum bond is formed between the layer and the sheet.

25. The method according to claim 20, wherein the applying comprises laminating or adhesively bonding the alkali-free glass to the glass substrate.
